(19) United States
(12) Patent Application Publication
(10) Pub. No.: US 2014/0159770 A1
(43) Pub. Date: Jun. 12, 2014

(54) Nonvolatile Logic Circuit

(71) Applicant: Alexander Mikhailovich Shukh, Savage, MN (US)

(72) Inventor: Alexander Mikhailovich Shukh, Savage, MN (US)

(21) Appl. No.: 13/712,840

(22) Filed: Dec. 12, 2012

(51) Int. Cl. H03K 19/173

(52) U.S. Cl. CPC H03K 19/173
USPC 326/37

(57) ABSTRACT

One embodiment of a nonvolatile logic circuit includes a logic circuit comprising a first source terminal, a second source terminal, at least one input terminal, and an output terminal to temporarily store a logic state with a power dependent status, a high voltage source coupled to the first source terminal, a low voltage source coupled to the second source terminal, an intermediate voltage source comprising an electrical potential higher than that of the low voltage source but lower than that of the high voltage source, and a nonvolatile reversible resistance element coupled to the output terminal at a first end and to the intermediate voltage source at a second end. The nonvolatile reversible resistance element preserves the logic state of the logic circuit which is controlled by an input signal applied to the at least one input terminal. Other embodiment are described and shown.

### CROSS-REFERENCE TO RELATED APPLICATIONS

This application is a continuation-in-part of U.S. patent application Ser. No. 13/283,465, filed on Oct. 27, 2011 and claims the benefit of U.S. provisional patent application No. 61/408,550, filed on Oct. 29, 2010 by the present inventor.

### FEDERALLY SPONSORED RESEARCH

Not Applicable

### SEQUENCE LISTING OR PROGRAM

Not Applicable

### RELEVANT PRIOR ART

U.S. Pat. No. 3,356,858, Dec. 5, 1967—Wanlass.

U.S. Pat. No. 7,339,818, Mar. 4, 2008—Katti et al.

U.S. Pat. No. 7,894,248, Feb. 22, 2011—Yu et al.

U.S. Pat. No. 8,004,882, Aug. 23, 2011—Katti et al.

U.S. Patent Application Publication No. 2010/0039136, Feb. 18, 2010—Chua-Eoan et al.

### BACKGROUND

A logic gate is an arrangement of electronically controlled switches used to proceed calculations in Boolean algebra. Logic gates can be constructed from relays, diodes, transistors and other elements. The logic gates constructed from the metal-oxide-semiconductor (MOS) transistors represent basic components of digital integrated circuits (ICs). The MOS logic gates are programmable and can perform different logic functions such as NOT, AND, OR, NAND, NOR and others.

FIG. 1 shows a circuit diagram of a complementary MOS (CMOS) inverter (or a logic gate) 10 for performing a NOT logic function according to a prior art disclosed by F. Wanlass in U.S. Pat. No. 3,356,858 (1967). The inverter 10 comprises a n-channel MOS transistor nT coupled to a low source voltage 12 (V_{SS}) and a p-channel MOS transistor pT coupled to a high source voltage 14 (V_{DD}). An input signal A at an input terminal 16 controls the nT and pT transistors. The inverter 10 performs the logic function NOT. An output signal Y at an output terminal 18 is an inversion of the input signal A (Y=A′). The CMOS inverter 10 found a broad application in digital ICs to perform the logic functions AND, OR, NAND, NOR and others. However the CMOS inverter 10 is volatile and loses its logic state when the power is off.

Alternatively, a magnetic tunnel junction (MTJ) is a nonvolatile reversible resistance element (RRE) employing a giant magneto-resistance (GMR) effect observed in a multilayer structure composed by at least two ferromagnetic layers separated by a thing oxide layer. When magnetizations of the ferromagnetic layers are parallel to each other, a tunneling resistance R_{P} of the MTJ is low and is referred to as a logic state “0”. When the magnetizations of the ferromagnetic layers are anti-parallel, the resistance R_{AP} of the MTJ is high and is referred to as a logic state “1”. In the MTJ one ferromagnetic layer, called a pinned or reference layer, has a fixed direction of the magnetization. The direction of the magnetization in the other layer that is called as a free or storage layer can be reversed from parallel to anti-parallel relatively to the direction of the magnetization in the pinned layer by applying an appropriate magnetic field or by running a spin polarized current through the MTJ in a direction perpendicular to a plane of the junction. The logic states “0” or “1” can be determined by comparing the resistance of the MTJ with a known reference resistance. The MTJ is a nonvolatile device. It doesn't lose its logic state when the power is off.

FIG. 2 shows a circuit diagram of a nonvolatile inverter 20 according to a prior art disclosed by R. Katti and T. Zhu in U.S. Pat. No. 7,339,818 (2008) and U.S. Pat. No. 8,004,882 (2011). The inverter 20 comprises a MTJ 22 that is coupled in series between two complimentary MOS transistors nT and pT. A logic state of the inverter 20 stores in the MTJ 22 and cannot be lost when the power is off. The MTJ 22 employs a spin polarized current for changing its logic state. Hence the logic state of the MTJ 22 can be controlled by a direction of the spin polarized current running through the junction during programming. To reverse the direction of the spin polarized current in the MTJ 22 the polarity of voltage sources 12 (V_{SS}) and 14 (V_{DD}) needs to be changed. A necessity to change the polarity of the voltages sources during an operation in the nonvolatile inverter 20 leads to several disadvantages.

For example, the CMOS inverter requires that a source terminal of the p-channel pT and n-channel nT transistors be connected to the high voltage source (V_{DD}) and to the low voltage source (V_{SS}), respectively. The opposite polarity of the voltage sources is not desirable since it leads to a substantial increase of power consumption by the inverter due to a power leakage in the transistors. Moreover the opposite polarity of the voltage sources might cause a substantial reduction of a saturation current of the transistors nT and pT. This obstacle might limit a possibility of the magnetization reversal in the MTJ 22 of the nonvolatile inverter 20 hence it might prevent the MTJ from memorizing the logic state of the inverter.

### SUMMARY

In accordance with one embodiment a nonvolatile logic circuit comprises: an output terminal, a high voltage source, a low voltage source, an intermediate voltage source, a pull-up circuit comprising at least one source terminal, at least one drain terminal, and at least one gate terminal, the at least one source terminal is coupled to the high voltage source and the at least one drain terminal is coupled to the output terminal; a pull-down circuit comprising at least one source terminal, at least one drain terminal, and at least one gate terminal, wherein the at least one source terminal of the pull-down circuit is coupled to the low voltage source and the at least one drain terminal of the pull-down circuit is coupled to the output terminal; at least one input terminal coupled to the at least one gate terminal of the pull-up circuit and to the at least one gate terminal of the pull-down circuit; and a nonvolatile reversible resistance element comprising a high resistance state and a low resistance state, the reversible resistance element is coupled to the output terminal at a first end and to the intermediate voltage source at a second end, wherein an electrical potential of the intermediate voltage source is higher than the electrical potential of the low voltage source but lower than the electrical potential of the high voltage source. The resistance state of the reversible resistance element is controlled by an input signal applied to the at least one input terminal. The reversible resistance element is a transition metal oxide element or a chalcogenide element.

In accordance with another embodiment a method for preserving a logic state of a nonvolatile logic circuit comprises: providing a logic circuit comprising, a first source terminal, a second source terminal, at least one input terminal, and an output terminal to temporarily store the logic state with a power dependent status; providing a high voltage source coupled to the first source terminal, providing a low voltage source coupled to the second source terminal, providing an intermediate voltage source comprising an electrical potential higher than that of the low voltage source but lower than that of the high voltage source, providing a nonvolatile reversible resistance element comprising a low resistance state and a high resistance state, the reversible resistance element is coupled to the output terminal at a first end and to the intermediate voltage source at a second end; and providing an input signal applied to the at least one input terminal, whereby preserving the logic state of the logic circuit by the nonvolatile reversible resistance element. The nonvolatile reversible resistance element is a chalcogenide element or a transition metal oxide element.

In accordance with yet another embodiment a nonvolatile logic circuit comprises: at least one input terminal, an output terminal, a high voltage source, a low voltage source, an intermediate voltage source comprising an electrical potential higher than that of the low voltage source but lower than that of the high voltage source, at least one p-channel transistor comprising a source terminal, a drain terminal, and a gate terminal, the source terminal is coupled to the high voltage source, the drain terminal is coupled to the output terminal, and the gate terminal is coupled to the at least one input terminal; at least one n-channel transistor comprising a source terminal, a drain terminal, and a gate terminal, the source terminal of the at least one n-channel transistor is coupled to the low voltage source, the drain terminal of the at least one n-channel transistor is coupled to the output terminal, and the gate terminal of the at least one n-channel transistor is coupled to the at least one input terminal; and a nonvolatile reversible resistance element comprising a low resistance state, a high resistance state, a first end, and a second end, the reversible resistance element is electrically coupled to the output terminal at the first end and to the intermediate voltage source at the second end, wherein the resistance state of the nonvolatile reversible resistance element is controlled by an input signal applied to the at least one input terminal. The reversible resistance element is a transition metal oxide element or a chalcogenide element.

These and other aspects and embodiments, their variations and modifications are described in greater detail in the drawings, detailed description, and claims.

### BRIEF DESCRIPTION OF THE DRAWINGS

In the following drawings closely related figures have the same number but different alphabetic suffixes.

FIG. 1 is circuit diagram of a volatile CMOS inverter according to a prior art.

FIG. 2 is a circuit diagram of a nonvolatile logic circuit with a magneto-resistive device according to a prior art.

FIG. 3 is a circuit diagram of a nonvolatile inverter according to a first embodiment.

FIGS. 4A and 4B illustrate a circuit diagram for describing a write operation of the nonvolatile inverter shown in the FIG. 3.

FIG. 5 is a schematic cross-sectional view of the nonvolatile inverter shown in the FIG. 3.

FIGS. 6A and 6B show a circuit diagram of a nonvolatile logic circuit in write operation according to a second embodiment.

FIGS. 7A and 7B show a schematic diagram of magnetic tunnel junctions with an out-of-plane magnetization direction.

FIG. 8 is a circuit diagram of a nonvolatile NAND logic gate with two input terminals according to a third embodiment.

FIG. 9 is a circuit diagram of a nonvolatile AND logic gate with two input terminals according to a fourth embodiment.

FIG. 10 is a circuit diagram of a nonvolatile NOR logic gate with two input terminals according to a fifth embodiment.

FIG. 11 is a circuit diagram of a nonvolatile OR logic gate with two input terminals according to a sixth embodiment.

FIG. 12 is a block diagram of a nonvolatile logic circuit with n-input terminals.

FIG. 13 is another view of the block diagram of the nonvolatile logic circuit shown in the FIG. 12.

FIG. 14 is a circuit diagram of a nonvolatile inverter with a reversible resistance element.

FIG. 15 is a schematic diagram of a transition metal oxide element used as a nonvolatile reversible resistance element.

FIG. 16 is a schematic diagram of a chalcogenide element used as a nonvolatile reversible resistance element.

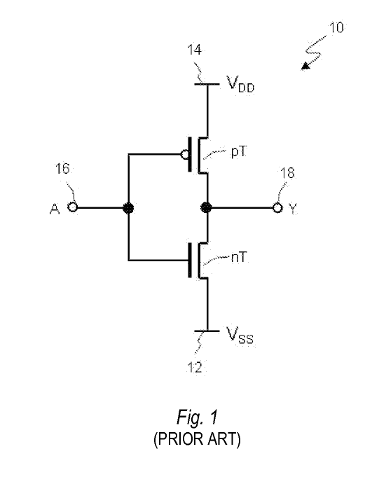

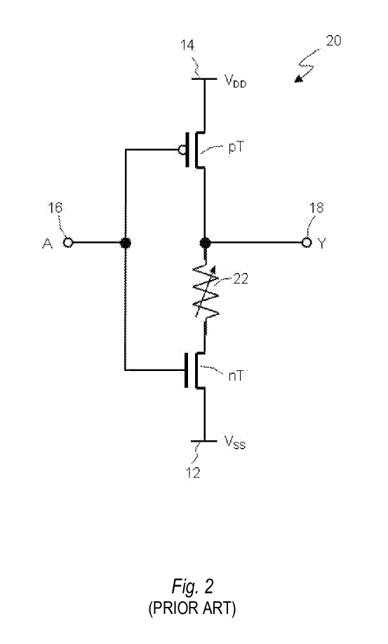

### EXPLANATION OF REFERENCE NUMERALS

nT, nTA, nTB n-channel MOS transistor
pT, pTA, pTB p-channel MOS transistor
10 volatile CMOS inverter (prior art)
12 low voltage source V_{SS}
14 high voltage source V_{DD}
16, 16A, 16B, . . . , 16N input terminal
18 output terminal
20 nonvolatile logic circuit (prior art)
22, 22A, 22B, 22C, 22D, 22E, 22F reversible resistance element (magneto-resistive element, transition metal oxide element, chalcogenide element)
30, 60, 80, 90, 100, 110, 120, 130 nonvolatile logic circuit
31, 31C free (or storage) ferromagnetic layer
32, 32A, 32B, 42, 42A, 42B source terminal
33, 33C pinned (or reference) ferromagnetic layer
34, 34A, 34B, 44, 44A, 44B drain terminal
35 tunnel barrier layer
36, 36A, 36B, 46, 46A, 46B gate terminal
38 intermediate (or medium) voltage source V_{M}
51 substrate
52, 62 source region
53 well
54, 64 drain region
56A, 56B, 56C, 58 contact
124 pull-down circuit
126 pull-up circuit
137 CMOS logic circuit
152 first electrode
154 second electrode
156, 166 storage layer
168 heater layer

### DETAILED DESCRIPTION

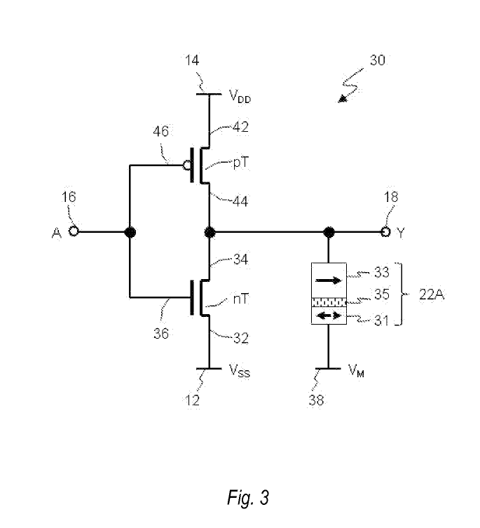

FIG. 3 illustrates a circuit diagram of a nonvolatile inverter 30 according to a first embodiment. The inverter 30 represents a nonvolatile logic circuit (or gate) that performs a logic function NOT. The inverter 30 comprises a n-channel MOS transistor nT and a complementary p-channel MOS transistor pT connected in series, and a magnetic tunnel junction (MTJ) 22A. A source terminal 32 of the nT transistor is connected to a low voltage source 12 (V_{SS}). Alternatively, a source terminal 42 of the pT transistor is connected to a high voltage source 14 (V_{DD}). Drain terminals 34 and 44 of the nT and pT transistors, respectively, are connected in common and to an output terminal 18. Gate terminals 36 and 46 of the nT and pT transistors, respectively, are connected in common and to an input terminal 16. The MTJ 22A is connected to the output terminal 18 at its first end and to an intermediate (or medium) voltage source 38 (V_{M}) at its second end. There is a following relation between potentials of the voltage sources V_{DD}, V_{M} and V_{SS}: V_{DD}>V_{M}>V_{SS}. Hence the potential of the voltage source V_{SS} is the lowest and the potential of the voltage source V_{DD} is the highest. The potential of the voltage source 38 can be equal to V_{M}=(V_{DD}−V_{SS})/2. If the low source 12 is connected to a ground terminal (V_{SS}=0), the potential of the voltage source 38 might be equal to V_{M}=V_{DD}/2.

The nonvolatile MTJ 22A comprises at least a free (or storage) layer 31, a pinned (or reference) layer 33, and a tunnel barrier layer 35 disposed between the ferromagnetic layers 31 and 33. In the first embodiment shown in FIG. 3 the free layer 31 is disposed adjacent the voltage source 38, and the pinned layer 33 is disposed adjacent the output terminal 18 and the drain terminals 34 and 44 of the nT and pT transistors. For exemplary purpose, the ferromagnetic layers 31 and 33 of the MTJ 22A are shown to have an in-plane magnetization. Direction of the magnetization in the free 31 and pinned 33 layers are shown by arrows. The direction of the magnetization in the pinned layer 33 (shown by solid arrow) is fixed by a manner generally known in the art, for example, by means of exchange coupling with an antiferromagnetic layer (not shown) or others. The magnetization in the free layer 31 (shown by dashed arrow) can be controlled. It has two stable states that are parallel or anti-parallel to the direction of the magnetization in the pinned layer 33. The direction of the magnetization in the free layer 31 can be reversed by means of a spin polarized current running through the MTJ 22A in a direction perpendicular to the layers plane; by an external magnetic field, or by other methods.

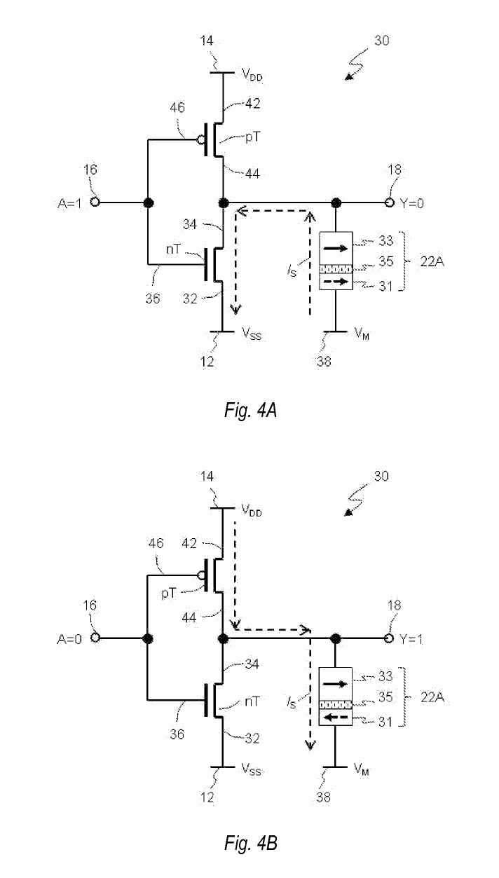

FIGS. 4A and 4B illustrate an operation of the nonvolatile inverter 30 shown in FIG. 3. In this embodiment, when a high input signal A=1 (logic “1”) appears at the input terminal 16, the nT transistor is ON but the pT transistor is OFF (FIG. 4A). The potential of the voltage source 38 is higher than that of the voltage source 12 (V_{M}>V_{SS}). Hence a spin polarized current I_{S} (shown by dashed arrows) appears in the inverter 30 running in a direction from the voltage source 38 to the low voltage source 12 through the MTJ 22A and the opened transistor nT. Conduction electrons move in a opposite to the current I_{S} direction. Hence in the MTJ 22A the electrons move from the pinned layer 33 into the free layer 31 through tunnel barrier layer 35. The conduction electrons running through the pinned layer 33 receive a substantial spin polarization. Being injected into the free layer 31 the spin polarized electrons interact with the magnetization of the layer and force it to switch in the direction parallel to the direction of the magnetization in the pinned layer 33 (shown by arrows). Resistance of the MTJ 22A with the parallel direction of the magnetizations in the free 31 and pinned 33 layers R_{P} has a low value that corresponds to a logic “0” or to the output signal Y=0. The logic state of the MTJ 22A can be determined comparing it with a resistance of a reference element (not shown).

FIG. 4B illustrates an operation of the nonvolatile inverter 30 when a low signal A=0 (logic “0”) appears at the input terminal 16. The transistor pT is ON but the transistor nT is OFF. Since the potential of the voltage source 14 is higher than that of the intermediate source 38 (V_{DD}>V_{M}), the spin polarized current I_{S} (shown by dashed arrows) in the MTJ 22A is running in direction from V_{DD} to V_{M}. Hence the spin polarized electrons of the current I_{S} in the MTJ 22A are moving from the free layer 31 to the pinned layer 33 through tunneling barrier layer 35. Being reflected by the pinned layer 33 the electrons force the direction of magnetization in the free layer 31 (shown by dashed arrow) to be oriented antiparallel to the direction of the magnetization in the pinned layer 33 (shown by solid arrow). The resistance R_{AP} of the MTJ 22A with the antiparallel magnetizations in the layer 31 and 33 has a high value that corresponds to a logic “1” or to the output signal Y=1. A correlation between the input A and output Y signals of the nonvolatile inverter 30 is summarized in Table 1 that is called a truth table.

TABLE 1

| | MTJ | |
|---|---|---|
| Input A | Resistance | Output Y |
| 0 | R_{AP} | 1 |
| 1 | R_{P} | 0 |

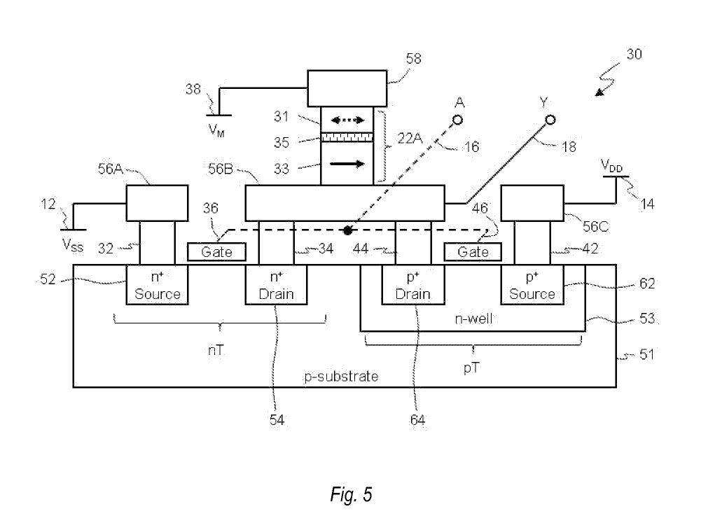

FIG. 5 shows a schematic cross-sectional view of the nonvolatile logic circuit 30 on wafer level. In this embodiment for exemplary purpose the inverter 30 is shown to be formed on a p-type substrate 51 that can be made of Si, Ge, GaAs or similar materials. The inverter 30 comprises the n-channel transistor nT, the p-channel transistor pT, and the MTJ 22A. The transistor nT has a heavily doped n⁺-type source 52 and drain 54 regions, and the gate terminal 36 over a thin layer of insulator (not shown) that is also called a gate oxide. The n⁺-source region 52 of the nT transistor is connected by means of the source terminal 32 and a contact 56A to the low voltage source 12. The n⁺-drain region 54 of the transistor nT by means of the drain terminal 34 and a contact 56B is simultaneously connected to the drain terminal 44 of the pT transistor, to the output terminal 18, and to the MTJ 22A.

The p-channel transistor pT requires an n-type body region, so an n-well 53 is formed in the p-substrate 51. The pT transistor has a complimentary structure to that of the nT transistor with p⁺-type source 62 and drain 64 regions, and the gate terminal 46. The gate terminals 36 and 46 of the nT and pT transistors, respectively, are connected in common and to the input terminal 16. The p⁺-source region 62 of the pT transistor is connected to the high voltage source 14 by means of the source terminal 42 and a contact 56C. The p⁺-drain region 64 of the transistor pT is connected to the n⁺-drain region 54 of the transistor nT by means of the drain terminals 44 and 34, and the contact 56B. Moreover, the n⁺-drain and p⁺-drain regions of the transistors nT and pT are connected to the MTJ 22A, and to the output terminal 18. The MTJ 22A comprises at least the pinned layer 33 adjacent the contact 56B, the free layer 31 adjacent a contact 58, and the tunnel barrier layer 35 disposed between the ferromagnetic layers 33 and 31. The free layer 31 is connected to the voltage source 38 by means of the contact 58. A structure of the MTJ 22A is simplified for exemplary purpose and may comprise several additional layers for providing a required performance.

There is wide latitude for the choice of materials and their thicknesses within various embodiments. The free ferromagnetic layer 31 may have a thickness of about 0.5 nm-3 nm. The free layer 31 can be made of ferromagnetic materials such as Fe, Co, Ni, CoFe, CoFeB, NiFe and/or similar, their based alloys and/or laminates. It should be appreciated that the free layer 31 may comprise various ferromagnetic materials with a substantial spin polarization and can vary dimensionally, including length, width and thickness depending on implementation and desirable magnetic, electrical and other characteristics without departing from the scope of the present application.

The pinned ferromagnetic layer 33 may have a thickness of about 0.5 nm-30 nm. The pinned layer 33 may comprise the ferromagnetic materials such as Fe, Co, Ni, CoFe, CoFeB, NiFe and/or similar, their based alloys and/or laminates. It should be appreciated that the pinned layer 33 may comprise various ferromagnetic materials with a substantial spin polarization and can vary dimensionally, including length, width and thickness depending on implementation and desirable magnetic, electrical and other characteristics without departing from the scope of the present application.

The tunnel barrier layer 35 may comprise an electrically insulating material such as, for example, Al₂O₃, MgO_{X}, TiO_{X}, Ta₂O₅, ZrO_{X}, HfO_{X}, Mg/MgO or similar, and their based laminates. The tunnel barrier layer 35 may have a thickness of about 0.5 nm-2 nm. It should be appreciated that the tunnel barrier layer 35 may vary dimensionally, including length, width and thickness depending on implementation and desirable electrical and other characteristics without departing from the scope of the present application.

The layers of the MTJ 22A can be made in a manner generally know in the art by deposition techniques (vacuum deposition, sputter deposition, ion-beam deposition and others), photolithography, etching, thermal treatment and other techniques used in a semiconductor and spintronics technologies. During formation of the tunnel barrier layer 35 an oxidation technique (plasma oxidation, oxidation by air or/and similar) may be used.

The terminals 32, 34, 42, 44 and the contacts 56A-56C, 58 can be made of a substantial metallic substance such as Al, AlCu, Cu, Ta/Au/Ta and/or similar materials, and/or their based laminates. The gate terminals 36 and 46 may be made of poly-Si, Al, AlCu and/or other similar materials and/or their based laminates. The terminals and contacts can be made using conventional MOS techniques.

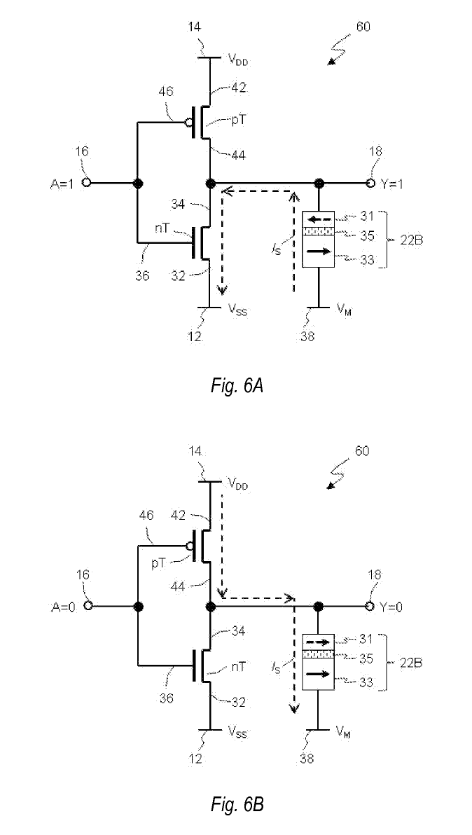

FIGS. 6A and 6B show an nonvolatile logic circuit 60 performing a buffer function according to a second embodiment. Similar to the nonvolatile inverter 30 disclosed above (FIG. 3), the nonvolatile buffer 60 utilizes CMOS technology with one n-channel and one p-channel transistor nT and pT, respectively, connected in series. A source terminal 32 of the transistor nT is connected to a low voltage source 32 (V_{SS}), and a source terminal 42 of the pT transistor is connected to a high voltage source 14 (V_{DD}). Gate terminals 36 and 46 of the transistors nT and pT, respectively, are connected in common and to an input terminal 16. Similarly, drain terminals 34 and 44 of the transistors nT and pT, respectively, are connected in common and to an output terminal 18. A MTJ 22B is connected to the output terminal 18 at its first end and to an intermediate voltage source 38 (V_{M}) at its second end. More specifically, a pinned layer 33 of the MTJ 22B is disposed adjacent the voltage source 38, and a free layer 33 is disposed adjacent the output terminal 18. Potentials of the voltage sources V_{SS}, V_{DD} and V_{M} satisfy to the following condition: V_{SS}<V_{M}<V_{DD}. The potential of the intermediate source 38 can be V_{M}=(V_{DD}−V_{SS})/2 or V_{M}=V_{DD}/2 when the terminal 32 is connected to a ground terminal. FIGS. 6A and 6B provide a schematic illustration of the MTJ 22B without disclosing for simplicity purpose other layers, which are apparent to people skilled in the art.

When a logic “1” appears at the input terminal 16 (A=1) of the logic circuit 60 (FIG. 6A) the transistor pT is OFF but the transistor nT is ON. A current I_{S} occurs in a circuit running in a direction from the intermediate source V_{M} to the low source V_{SS} through the MTJ 22B and the transistor nT. The direction of the current I_{S} (shown by dashed arrows) is opposite to that of the conduction electrons, which run from the free layer 31 into the pinned layer 33 through tunnel barrier layer 35. The spin polarized electrons force the magnetization (shown by a dashed arrow) in the free layer 31 to be oriented antiparallel to the direction of the magnetization in the pinned layer 33 (shown by solid arrow). The MTJ 22B with the antiparallel magnetizations in the layers 31 and 33 has a high resistance state R_{AP} that corresponds to a logic “1” at the output 18. Hence the nonvolatile logic circuit 60 performs as a logic buffer, wherein the logic state at its input terminal 16 (A=1) is similar to that at the output terminal 18 (Y=1).

FIG. 6B shows a circuit diagram of the logic circuit 60 when a logic “0” appears at the input terminal 16 (A=0). The transistor pT is ON and the transistor nT is OFF. The current I_{S} is running from the voltage source V_{DD} to the voltage source V_{M} through the transistor pT and the MTJ 22B. Hence the spin polarized electrons in the MTJ 22B run in the opposite direction from the pinned layer 33 into the free layer 31 through the tunnel barrier layer 35. The electrons force the magnetization of the free layer 31 (shown by dashed arrow) in the direction parallel to the direction of the magnetization of the pinned layer 33 (shown by solid arrow). The parallel orientation of the magnetizations in the free 31 and pinned 33 layers corresponds to a low resistance state R_{P} of the MTJ 22B or to a logic “0”. Hence logic “0” at the input 16 results in the logic “0” at the output 18 of the nonvolatile logic circuit 60. A truth table of the nonvolatile logic circuit 60 is given in Table 2.

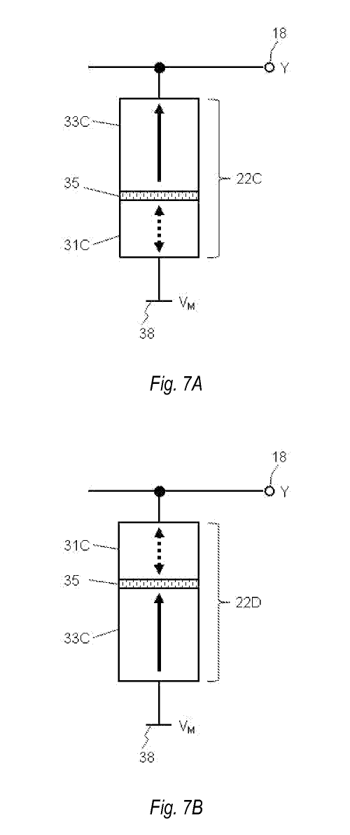

The logic circuits shown in FIG. 3-FIG. 6 disclosed above employ the MTJs 22A and 22B with the in-plane magnetization in the free 31 and pinned 33 layers. However the direction of the magnetization in the ferromagnetic layers 31 and 33 can be directed perpendicular to the layers plane or out-of plane as shown in FIGS. 7A and 7B. The MTJ 22C (FIG. 7A) can be used in the nonvolatile logic circuit 30 shown in FIGS. 3, 4A, 4B and 5. The MTJ 22D (FIG. 7B) can be used in the nonvolatile logic circuit 60 shown in FIGS. 6A and 6B.

TABLE 2

| | MTJ | |
|---|---|---|
| Input A | Resistance | Output Y |
| 0 | Rₚ | 0 |
| 1 | R_{Ap} | 1 |

The perpendicular MTJs 22C and 22D can have a substantially higher thermal stability than that of the in-plane MTJs with comparable dimensions due to a substantial intrinsic crystalline anisotropy of the perpendicular ferromagnetic materials. Moreover, the perpendicular MTJs 22C and 22D can have any shape including a round that is not possible in many cases for the in-plane MTJs 22A and 22B, which frequently have to use an elliptical shape. Necessity to use the elliptical shape of MTJ results from the rather week intrinsic crystalline anisotropy of the in-plane ferromagnetic materials.

The free layer 31C may have a thickness of about 0.5 nm-3 nm. The free layer 31C can comprise ferromagnetic materials such as Fe, Co, Ni, CoFe, CoFeB, NiFe, FePt, Co/Pt, Co/Pd, CoFe/Pt, Fe/Pt, Ni/Cu and/or similar, their based alloys and/or laminates. It should be appreciated that the free layer 31C may comprise various ferromagnetic materials with a substantial spin polarization and perpendicular anisotropy or out-of plane direction of the magnetization. The free layer 31C can vary dimensionally, including length, width and thickness depending on implementation and desirable magnetic, electrical and other characteristics without departing from the scope of the present application.

The pinned layer 33C may have a thickness of about 0.5 nm-30 nm. The pinned layer 33C my comprise ferromagnetic materials such as Fe, Co, Ni, CoFePt, CoPtTa, FePt, Co/Pt, Co/Pd, CoFe/Pt, CoFeB/Pt, Ni/Cu and/or similar, their based alloys and/or laminates. It should be appreciated that the pinned layer 33C may comprise various ferromagnetic materials with a substantial spin polarization and perpendicular anisotropy or out-of plane direction of the magnetization. The pinned layer 33C can vary dimensionally, including length, width and thickness depending on implementation and desirable magnetic, electrical and other characteristics without departing from the scope of the present application.

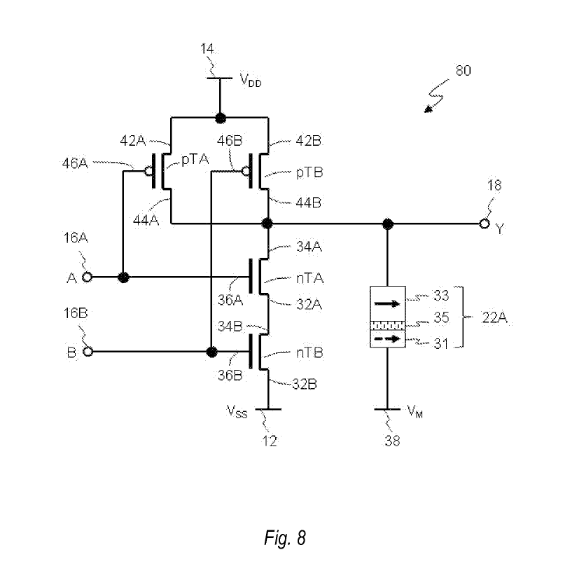

FIG. 8 shows a circuit diagram of a nonvolatile logic circuit 80 with two input terminals 16A and 16B that performs a NAND logic function. The logic circuit 80 comprises two n-channel MOS transistors nTA and nTB connected in series to each other, two p-channel MOS transistors pTA and pTB connected in parallel to each other, and a MTJ 22A. The n-channel transistors nTA and nTB are disposed between a low voltage source 12 (V_{SS}) and an output terminal 18. A source terminal 32B of the transistor nTB is connected to the low voltage source 12 and a drain terminal 34A of the transistor nTA is connected to the output terminal 18. The transistors pTA and pTB are disposed between a high voltage source 14 (V_{DD}) and the output terminal 18. Their source terminals 42A and 42B are connected to the high voltage source 14, and drain terminals 44A and 44B are connected to the output terminal 18. A gate terminal 36A of the transistor nTA is connected both to a gate terminal 46A of the transistor pTA and to the input terminal 16A. Likewise a gate terminal 36B of the transistor nTB is connected both to a gate terminal 46B of the transistor pTB and to the input terminal 16B. The MTJ 22A is connected to an intermediate voltage source 38 (V_{M}) at its first end that is adjacent a free layer 31. A second end of the MTJ 22A, which is adjacent a pinned layer 33, is connected to the output terminal 18.

If either input signal A or B is equal to a logic “0”, at least one of the n-channel transistors nTA or nTB will be OFF, breaking a current flow from the source V_{M} to the source V_{SS} through the MTJ 22A. However at least one of the p-channel transistors pTA or pTB will be ON, creating a path for current from the voltage source V_{DD} to the voltage source V_{M} through the MTJ 22A. Hence the mutual direction of the magnetizations (shown by arrows) in the free 31 and pinned 33 layers of the MTJ 22A will be antiparallel. It corresponds to a high resistance R_{AP} of the MTJ 22A or to a logic “1” of the output signal Y.

If both input signals are equal to a logic “1” (A=B=1), both n-channel transistors nTA and nTB will be ON and both p-channel transistors pTA and pTB will be OFF. Hence the current will flow from the intermediate voltage source V_{M} to the low voltage source V_{SS} through the MTJ 22A and the transistors nTA and nTB. This direction of the current will produce a parallel direction of the magnetizations (shown by arrows) in the free 31 and pinned 33 layers. The parallel orientation of the magnetizations results in a low resistance Rₚ of the MTJ 22A that corresponds to a logic “0” of the output signal Y. A truth table of the logic circuit 80 is given in Table 3.

TABLE 3

| | | MTJ | |
|---|---|---|---|
| Input A | Input B | Resistance | Output Y |
| 0 | 0 | R_{AP} | 1 |
| 0 | 1 | R_{AP} | 1 |
| 1 | 0 | R_{AP} | 1 |
| 1 | 1 | R_{P} | 0 |

N-input nonvolatile logic circuit performing NAND logic function can be composed by using N n-channel transistors connected in series to each other, N p-channel transistors connected in parallel to each other, and at least one MTJ, connected to the output terminal of the logic circuit. The series n-channel transistors are disposed between the output terminal and the low voltage source V_{SS}. The parallel p-channel transistors are disposed between the high voltage source V_{DD} and the output terminal. The MTJ is positioned between the intermediate voltage source V_{M} and the output terminal, wherein the pinned layer of the MTJ is disposed adjacent the output terminal and the free layer is disposed adjacent the intermediate voltage source V_{M}. A gate terminal of one of the n-channel transistors is connected in common with a gate terminal of one of the p-channel transistors, and both are connected to one of the N-input terminals of the logic circuit.

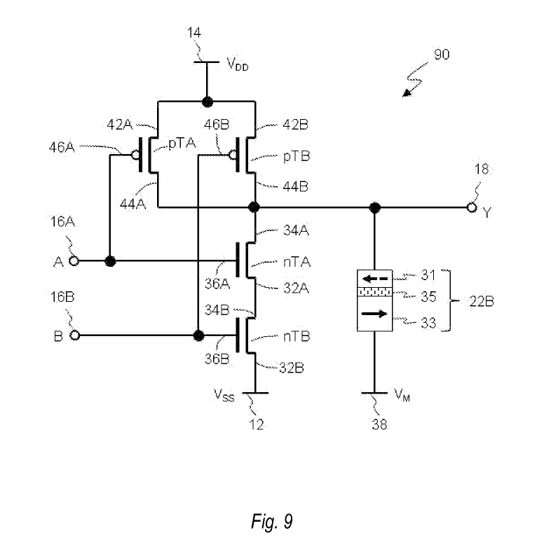

FIG. 9 shows a circuit diagram of a 2-input nonvolatile logic circuit 90 according to a fourth embodiment. The logic circuit 90 performs a logic function AND. The circuit 90 has a similar circuit diagram to that of the nonvolatile logic circuit 80 shown in FIG. 8 but comprises a MTJ 22B, wherein the free layer 31 is disposed adjacent the output terminal 18 and the pinned layer 33 is disposed adjacent the intermediate voltage source 38. A reversed position of the free 31 layer relatively to the output terminal 18 in the logic circuit 90 compared to that in the logic circuit 80 results in an reversed polarity of the output signal Y when similar combinations of the signals A and B appear at the input terminals 16A and 16B. A truth table of the nonvolatile logic circuit 90 performing AND function is given in Table 4.

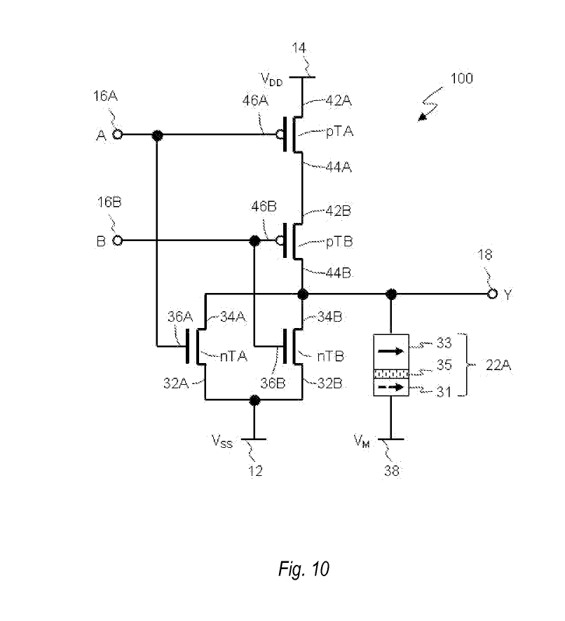

FIG. 10 illustrates a circuit diagram of 2-input nonvolatile logic circuit 100 according to a fifth embodiment. The logic circuit 100 performs a logic function NOR. The circuit 100 comprises two n-channel transistors nTA and nTB connected in parallel to each other, two p-channel transistors

TABLE 4

| | | MTJ | |
|---|---|---|---|
| Input A | Input B | Resistance | Output Y |
| 0 | 0 | Rₚ | 0 |
| 0 | 1 | Rₚ | 0 |
| 1 | 0 | Rₚ | 0 |
| 1 | 1 | R_{Ap} | 1 |

pTA and pTB connected in series, and a MTJ 22A. Source terminals 32A and 32B of the n-channel transistors nTA and nTB, respectively, are connected to a low voltage source 12 (V_{SS}). Drain terminals 34A and 34B of the n-channel transistors pTA and pTB, respectively, are connected simultaneously to an output terminal 18, to a drain terminal 44B of the p-channel transistor pTB, and to the MTJ 22A at its first end. A source terminal 42A of the transistor pTA is connected to a high voltage source 14 (V_{DD}). Gate terminals 36A and 46A of the nTA and pTA transistors, respectively, are connected in common and to an input terminal 16A. Similarly the gate terminals 36B and 46B of the transistors nTB and pTB are connected in common and to the input terminal 16B. A second end of the MTJ 22A is electrically connected to an intermediate voltage source 38 (V_{M}) having a free layer 31 disposed adjacent the second end.

If either one or both input signals A or B are equal to a logic “1” (FIG. 10), at least one of the n-channel transistors nTA or nTB will be ON but at least one of the p-channel transistors pTA or pTB will be OFF. A current flow in a direction from the intermediate source V_{M} to the low source V_{SS} through the MTJ 22A and at least one of the n-channel transistors nTA and nTB will occur. Hence spin polarized electrons of the current will run from the pinned layer 33 into the free layer 31 through tunnel barrier layer 35. As a result, a parallel orientation of the magnetizations in the ferromagnetic layers 31 and 33 corresponding to a low resistance R_{P} of the MTJ 22A will be formed. The low resistance R_{P} corresponds to a logic “0” at the output (Y=0).

The output signal Y=1 will occur when the input signals A=B=0 appear. Both p-channel transistors pTA and pTB will be ON but the n-channel transistors nTA and nTB will be OFF. The current will flow from the high voltage source V_{DD} to the intermediate source V_{M} through MTJ 22A and both the p-channel transistors pTA and pTB. This direction of the write current causes the antiparallel orientation of the magnetizations in the free 31 and pinned 33 layers corresponding to a high resistance R_{AP} of the MTJ 22A or to a logic “1” at the output (Y=1). A truth table of the logic circuit 100 is given in Table 5.

TABLE 5

| | | MTJ | |
|---|---|---|---|
| Input A | Input B | Resistance | Output Y |
| 0 | 0 | R_{AP} | 1 |
| 0 | 1 | R_{P} | 0 |
| 1 | 0 | R_{P} | 0 |
| 1 | 1 | R_{P} | 0 |

NOR nonvolatile logic circuit (FIG. 10) comprising N input terminals can be composed by using N n-channel transistors connected in parallel to each other, N p-channel transistors connected in series to each other, and at least one MTJ, connected to the output terminal of the logic circuit. The parallel n-channel transistors are disposed between the output terminal and a low voltage source V_{SS}. The series p-channel transistors are disposed between a high voltage source V_{DD} and the output terminal. The MTJ is disposed between the output terminal and an intermediate voltage source V_{M}, wherein a pinned layer of the MTJ is disposed adjacent the output terminal and a free layer is disposed adjacent the intermediate voltage source V_{M}. A gate terminal of one of the n-channel transistors is connected in common with a gate terminal of one of the p-channel transistors, and both are connected to one of the input terminals of the logic circuit.

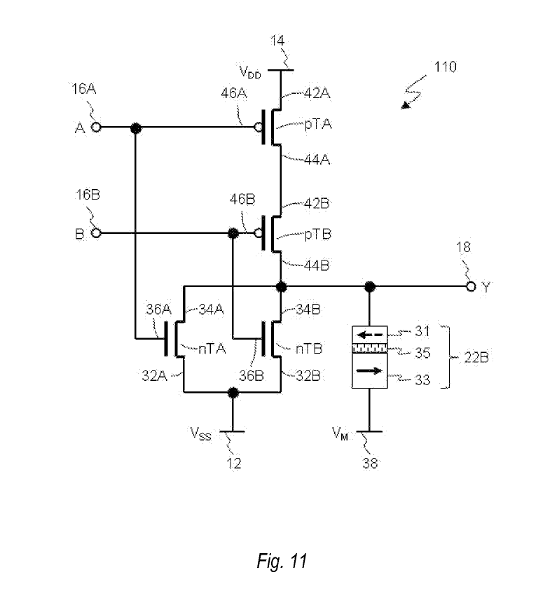

FIG. 11 illustrates a circuit diagram of a 2-input nonvolatile logic circuit 110 according to a sixth embodiment. The logic circuit 110 performs a logic function OR. The circuit 110 has the circuit diagram similar to that of the nonvolatile logic circuit 100 shown in FIG. 10 but comprises the MTJ 22B. In the MTJ 22B the free layer 31 is disposed adjacent the output terminal 18 and the pinned layer 33 is disposed adjacent the voltage source V_{M}. The reversed order of the ferromagnetic layers 31 and 33 in the MTJ 22B of the circuit 110 compared to that of the MTJ 22B employed in the circuit 100 results in the reversed magnetization direction of the free layer 31 when similar combination of the input signals is applied. A truth table of the nonvolatile logic circuit 110 is given in Table 6.

TABLE 6

| | | MTJ | |
|---|---|---|---|
| Input A | Input B | Resistance | Output Y |
| 0 | 0 | Rₚ | 0 |
| 0 | 1 | R_{Ap} | 1 |
| 1 | 0 | R_{Ap} | 1 |
| 1 | 1 | R_{AP} | 1 |

In general, each of the logic circuits 30, 60, 80-110 disclosed above is realized by using two complementary MOS (CMOS) circuits, a nMOS pull-down circuit comprising at least one n-channel transistor to connect the output terminal 18 to a low voltage source 12 (V_{SS}), a pMOS pull-up circuit comprising at least one p-channel transistor to connect the output terminal 18 to a high voltage source 14 (V_{DD}), and a MTJ 22 to store the output signal Y. The MTJ 22 is connected to the output terminal 18 at its first end and to an intermediate voltage source 38 (V_{M}) at its second end. The pull-down and pull-up circuits are arranged such that one is ON and the other is OFF for any input pattern.

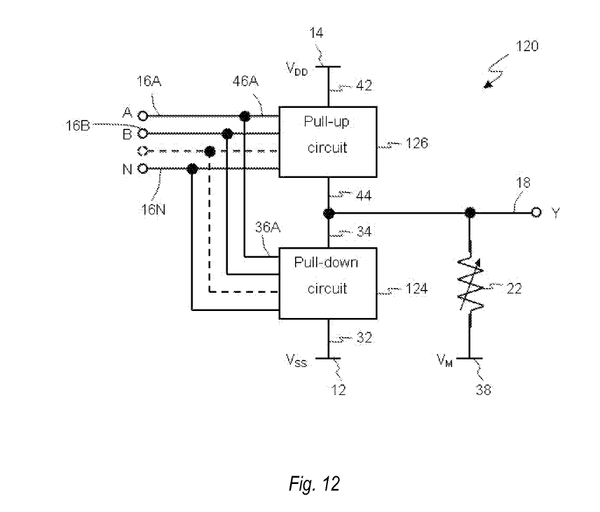

A generic block diagram of a nonvolatile logic circuit 120 with N input terminals 16B, 16B, . . . , and 16N is shown in FIG. 12. The logic circuit 120 comprises the pull-down circuit 124, the pull-up circuit 126, and the MTJ 22. The pull-down circuit 124 is connected to the low voltage source 12 by its source terminal 32 and to the output terminal 18 by its drain terminal 34. The pull-up circuit 124 is connected to the high voltage source 14 by its source terminal 42 and to the output terminal 18 by its drain terminal 44. For exemplary purpose the pull-down 124 and pull-up 126 circuits are shown comprising only one source and drain terminal each. Gate terminals 36A and 46A of the pull-down 124 and pull-up 126 circuits, respectively, are connected to the input terminal 16A and so on. The MTJ 22 is connected to the output terminal 18 at its first end and to an intermediate voltage source 38 at its second end. There is a following relation between a voltage potential of the sources: V_{SS}<V_{M}<V_{DD}. The voltage potential of the intermediate source V_{M} can be: V_{M}=(V_{DD}−V_{SS})/². If the potential of the low voltage source V_{SS} is connected to a ground (V_{SS}=0), the potential of the intermediate source can be equal to V_{M}=V_{DD}/2.

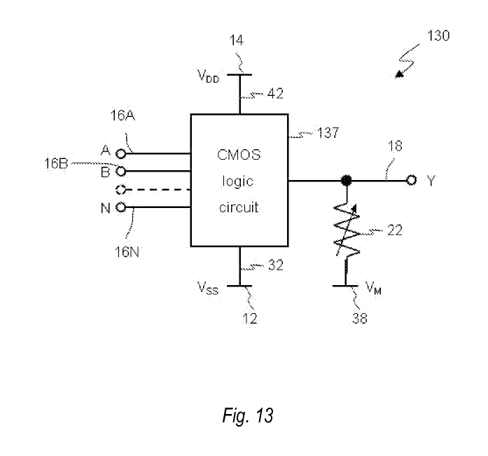

FIG. 13 illustrates another view of the block diagram of the nonvolatile logic circuit 120 shown in FIG. 12. The circuit 130 comprises a CMOS logic block 137 having N input terminals 16A, 16B, . . . , 16N and an output terminal 18. The logic block 137 is connected to a low voltage source 12 (V_{SS}) by mean of one source terminal 32 and to a high voltage source 14 (V_{DD}) by another source terminal 42. The logic state of the CMOS circuit 137 is controlled by an input signal A, B, . . . , N, or their combination applied to at least one of the input terminals 16A-16N. The CMOS logic circuit is volatile and loses its logic state when the power is off. A nonvolatile MTJ 22 is connected to the output terminal 18 at its first end to an intermediate voltage source 38 (V_{M}) at its second end. The nonvolatile MTJ 22 preserves the logic state of the CMOS circuit 137 during a loss of the power.

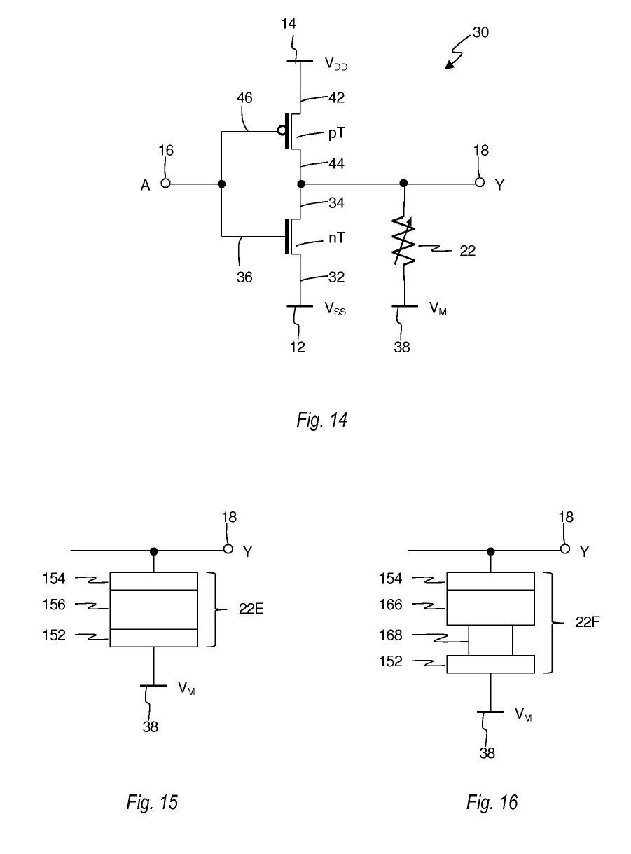

Various nonvolatile reversible resistance elements (RRE) can be used instead of the MTJs 22A-22D in the present embodiments. For example, the MTJ can be replaced by a RRE that is used in a resistive random access memory (RRAM or ReRAM), in a phase-change random access memory (PRAM or PCRAM), in a conductive bridging random access memory (CBRAM), or by other similar device. In the present embodiments the MTJs are shown for exemplarily purpose. FIG. 14 illustrates a nonvolatile inverter 30 which uses a nonvolatile RRE 22. The RRE 22 is electrically coupled to the output terminal 18 at its first end and to the intermediate voltage source V_{M} at its second end. The RRE 22 has a reversible resistance with a low resistance state (logic “0”) and a high resistance state (logic “1”). The resistance states can be reversed by changing a direction of current running through the RCE or by reversing a voltage polarity applied to the resistance element.

FIG. 15 is a schematic diagram showing a configuration of a nonvolatile RRE 22E that is a transition metal oxide (TMO) element which is used in the RRAM. The TMO element 22E can comprise a first electrode 152, a second electrode 154, and a storage layer 156 interposed between the electrodes. The TMO element 22E is electrically coupled to the output terminal 18 of the volatile CMOS logic circuit (not shown) at its first end and to the intermediate voltage source V_{M} at its second end. The TMO element 22E has a reversible resistance with substantially different two resistance states: a low resistance state corresponding to logic “0” and a high resistance state corresponding to logic “1”. The resistance state of the TMO element can be reversed by changing a direction of current running through the element.

The storage layer 156 can be made of transition metal oxides such as perovskite-like metal oxides or binary metal oxides. The perovskite-like metal oxides can include Pr_{0.7}Ca_{0.3}MnO₃, SrTiO3, NbSrTiO₃, NbSrZrO₃ CrSrZrO3, CrSrTiO₃ and/or similar materials. The binary metal oxides can include NiₓO_{y}, TiₓO_{y}, CuₓO_{y}, TiₓO_{y}, O_{y}, ZrₓO_{y}, HfₓO_{y}, TaₓO_{y}, WₓO_{y}, FeₓO_{y}, CoₓO_{y}, ZnₓO_{y} and/or similar materials. The first and second electrodes can be made of materials consisting of a group that includes but is not limited to Ti, Ni, Cu, Ru, Pd, Ag, W, Ir, Pt, Au, Al, their based alloys and multilayers.

FIG. 16 is a schematic diagram showing the configuration of the RRE 22F that is a chalcogenide element which is used in the PCRAM. The chalcogenide element 22F can comprise a first electrode 152, a heater layer 168, a storage layer 166, and a second electrode 154 that are stacked in order. An area of the first electrode 152 is greater than that of the heater layer 168. The second electrode 154 can have the same shape as the storage layer 166.

The resistance of the storage layer 166 depends on a crystal structure of the layer. The resistance is low when the layer 166 has a polycrystalline structure (logic “0”), and the resistance is high when the layer 166 has an amorphous structure (logic “1”). The crystal structure of the storage layer 166 can be controlled by a magnitude and duration of a current pulse applied to the storage layer 166, such that the storage layer can have a polycrystalline or amorphous structure. The magnitude and duration of the write current can be controlled by the CMOS logic circuit providing different values of the current magnitudes and durations during ON state of the pull-up and pull-down circuits.

The storage layer 166 can be made of a phase-change material, which can be set into a polycrystalline or amorphous state by a heat generated during writing. The material of the storage layer 166 can include a chalcogenide material such as GeSbTe, InSbTe, AgInSbTe, GeSnTe, GeSb, GeTe, AgSbSe, SbSe, SbTe, InSe, TeAsSiGe and similar.

The heater layer 168 has a direct contact with the storage layer 166. An area of the heater layer 168 can be smaller than the area of the storage layer 166. It allows to reduce a write current and a size of an active area in the storage layer 166. The heater layer 168 can be made from a conductive material selected from a group consisting of TiN, TiAlN, TiBN, TiSiN, TiW, Ti, TaN, TaAlN, TaBN, TaSiN, Ta, WN, WAlN, WBN, WSiN, ZrN, ZrAlN, ZrBN, ZrSiN, MoN, Mo, Al, Cu, AlCu, AlCuSi, WSi and similar. Moreover, the heater layer 168 may be made of the same material as the first electrode 152.

The material of the first electrode 152 and the second electrode 154 can include a metal having a high melting point such as Ta, Mo, W, Ti and similar.

While the specification of this application contains many specifics, these should not be construed as limitations on the scope of the application or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

It is understood that the above application is intended to be illustrative, and not restrictive. Many other embodiments will be apparent to those of skill in the art upon reviewing the above description. The scope of the embodiments should be, therefore, determined with reference to the appended claims, along with the full scope of equivalents to which such claims are entitled.

What is claimed is:

1. A nonvolatile logic circuit comprising:
an output terminal;
a high voltage source;
a low voltage source;
an intermediate voltage source;
a pull-up circuit comprising at least one source terminal, at least one drain terminal, and at least one gate terminal, wherein the at least one source terminal is coupled to the high voltage source and the at least one drain terminal is coupled to the output terminal;
a pull-down circuit comprising at least one source terminal, at least one drain terminal, and at least one gate terminal, wherein the at least one source terminal of the pull-down circuit is coupled to the low voltage source and the at least one drain terminal of the pull-down circuit is coupled to the output terminal;
at least one input terminal coupled to the at least one gate terminal of the pull-up circuit and to the at least one gate terminal of the pull-down circuit; and
a nonvolatile reversible resistance element comprising a high resistance state and a low resistance state, the reversible resistance element is coupled to the output terminal at a first end and to the intermediate voltage source at a second end,
wherein an electrical potential of the intermediate voltage source is higher than the electrical potential of the low voltage source but lower than the electrical potential of the high voltage source.

2. The nonvolatile logic circuit of claim 1, wherein the resistance state of the reversible resistance element is controlled by an input signal applied to the at least one input terminal.

3. The nonvolatile logic circuit of claim 1, wherein the pull-up circuit comprises at least one p-channel MOS transistor.

4. The nonvolatile logic circuit of claim 1, wherein the pull-down circuit comprises at least one n-channel MOS transistor.

5. The nonvolatile logic circuit of claim 1, wherein the nonvolatile reversible resistance element is a transition metal oxide element comprising a first electrode, a second electrode, and a storage layer disposed between the first and second electrodes.

6. The nonvolatile logic circuit of claim 5, wherein the storage layer comprises a reversible resistance.

7. The nonvolatile logic circuit of claim 1, wherein the nonvolatile reversible resistance element is a chalcogenide element comprising a first electrode, a heater layer, a storage layer, and a second electrode, the heater and storage layers are disposed between the first and second electrodes.

8. The nonvolatile logic circuit of claim 7, wherein the storage layer comprises a reversible crystal structure.

9. A method for preserving a logic state, the method comprising:
providing a logic circuit comprising, a first source terminal, a second source terminal, at least one input terminal, and an output terminal to temporarily store the logic state with a power dependent status;
providing a high voltage source coupled to the first source terminal;
providing a low voltage source coupled to the second source terminal;
providing an intermediate voltage source comprising an electrical potential higher than that of the low voltage source but lower than that of the high voltage source;
providing a nonvolatile reversible resistance element comprising a low resistance state and a high resistance state, the reversible resistance element is coupled to the output terminal at a first end and to the intermediate voltage source at a second end; and
providing an input signal applied to the at least one input terminal, whereby
preserving the logic state of the logic circuit by the nonvolatile reversible resistance element.

10. The method of claim 9, wherein the volatile logic circuit comprises at least one p-channel transistor and at least one n-channel transistor coupled to each other.

11. The method of claim 9, wherein the nonvolatile reversible resistance element is a chalcogenide element.

12. The method of claim 9, wherein the nonvolatile reversible resistance element is a transition metal oxide element.

13. A nonvolatile logic circuit comprising:
at least one input terminal;
an output terminal;
a high voltage source;
a low voltage source;
an intermediate voltage source comprising an electrical potential higher than that of the low voltage source but lower than that of the high voltage source;
at least one p-channel transistor comprising a source terminal, a drain terminal, and a gate terminal, the source terminal is coupled to the high voltage source, the drain terminal is coupled to the output terminal, and the gate terminal is coupled to the at least one input terminal;
at least one n-channel transistor comprising a source terminal, a drain terminal, and a gate terminal, the source terminal of the at least one n-channel transistor is coupled to the low voltage source, the drain terminal of the at least one n-channel transistor is coupled to the output terminal, and the gate terminal of the at least one n-channel transistor is coupled to the at least one input terminal; and
a nonvolatile reversible resistance element comprising a low resistance state, a high resistance state, a first end, and a second end, the reversible resistance element is electrically coupled to the output terminal at the first end and to the intermediate voltage source at the second end,
wherein the resistance state of the nonvolatile reversible resistance element is controlled by an input signal applied to the at least one input terminal.

14. The nonvolatile logic circuit of claim 13, wherein the nonvolatile reversible resistance element is a chalcogenide element comprising a first electrode, a heater layer, a storage layer having a reversible crystal structure, and a second electrode, the heater and storage layers are disposed between the first and second electrodes.

15. The nonvolatile logic circuit of claim 13, wherein the nonvolatile resistance change element is a transition metal oxide element comprising a first electrode, a storage layer comprising a transition metal oxide having a reversible resistance, and a second electrode, the storage layer is disposed between the first and second electrodes.
